(19) United States
(12) Patent Application Publication
(10) Pub. No.: US 2007/0241326 A1
(43) Pub. Date: Oct. 18, 2007

(54) ORGANIC LIGHT EMITTING DIODE DISPLAY AND MANUFACTURING METHOD THEREOF

(75) Inventors: Tae-Whan Kim, Seoul (KR); Kyoung-Phil Kim, Gunpo-si (KR); Dong-Chul Choo, Seoul (KR); Sang-Min Han, Suwon-si (KR); Dae-Uk Lee, Goyang-si (KR)

Correspondence Address: CANTOR COLBURN, LLP, 55 GRIFFIN ROAD SOUTH, BLOOMFIELD, CT, 06002, US

(73) Assignees: SAMSUNG ELECTRONICS CO., LTD., Suwon-si (KR); Industry-University Cooperation Foundation, Hanyang University, Seoul (KR)

(21) Appl. No.: 11/736,982

(22) Filed: Apr. 18, 2007

(30) Foreign Application Priority Data
Apr. 18, 2006 (KR) 10-2006-0034958
Oct. 2, 2006 (KR) 10-2006-0097076

(51) Int. Cl. H01L 29/08

(52) U.S. Cl. 257/40

(57) ABSTRACT

An organic light emitting device and manufacturing method thereof includes a substrate; a first electrode formed on the substrate; a second electrode formed on the first electrode; an light emitting member interposed between the first electrode and the second electrode; and a photonic crystal member disposed in proximity to the substrate.

This application claims priority to Korean Patent Applications No. 10-2006-0034958 filed on Apr. 18, 2006 and No. 10-2006-0097076 filed on Oct. 2, 2006, and all the benefits accruing therefrom under 35 U.S.C. § 119, the contents of which in their entirety are herein incorporated by reference.

### BACKGROUND OF THE INVENTION

(a) Field of the Invention

The present invention relates to an organic light emitting device (“OLED”) and a manufacturing method thereof.

(b) Description of the Related Art

Recently, lightweight and thin monitors and televisions have been in demand, and to this end, liquid crystal displays (“LCDs”) are commonly replacing conventional cathode ray tubes (“CRTs”).

However, since an LCD is a passive light emitting device, not only are additional backlights required for such a device, there are additional problems associated with a traditional LCD, such as the response speed and the relatively small viewing angle, for example.

More recently, OLEDs have been utilized in the fabrication of display devices to overcome such problems. More specifically, an OLED includes two electrodes and an emitting layer interposed therebetween, wherein an electron injected from one electrode and a hole injected from the other electrode are recombined in the emitting layer to generate an exciton, which in turn releases energy, thereby emitting light. Since an OLED is a self-emitting light device that does not require an additional light source, the power consumption is low.

In order to further decrease the power consumption, the light emitting efficiency of an OLED should be raised. Light emitting efficiency is determined by light emitting material efficiency, internal quantum efficiency (which is a ratio of the number of carriers injected from an electrode to the number of photons generated in an emitting layer), and external quantum efficiency (which is a ratio of the number of photons generated in the emitting layer to the number of photons emitted to the outside).

Of those parameters, the external quantum efficiency decreases while light emitted from the emitting layer passes through a plurality of layers having different refractive indexes. Particularly, when light is reflected or scattered due to the difference between refractive indexes of respective layers so that light emitted toward the front is decreased, the external quantum efficiency may be considerably decreased.

### BRIEF SUMMARY OF THE INVENTION

Aspects of the present invention increase the light emitting efficiency of an OLED.

According to an exemplary embodiment of the present invention, an organic light emitting device includes a substrate; a first electrode formed on the substrate; a second electrode formed on the first electrode; a light emitting member interposed between the first electrode and the second electrode; and a photonic crystal member formed proximate the substrate.

In one aspect, the photonic crystal member may be disposed between the substrate and the first electrode and comprises a porous structure having a plurality of holes and a thin film in contact with the porous structure, the thin film having a different refractive index from the porous structure.

In one aspect, the porous structure may comprise alumina.

In another aspect, the porous structure may comprise silicon (Si).

The thin film may comprise one of silicon oxide and silicon nitride.

A diameter of the holes of the porous structure may be may be from about tens of nanometers to about hundreds of nanometers.

The photonic crystal member may be disposed under the substrate and have a plurality of holes therein.

The photonic crystal member may comprise alumina.

A diameter of the holes may be from about tens of nanometers to about hundreds of nanometers.

An exemplary embodiment of the present invention also provides a method of forming an organic light emitting device, including forming an alumina structure having a plurality of holes therein; disposing the alumina structure on a substrate; forming a first electrode on the substrate; forming a light emitting member on the first electrode; and forming a second electrode on the light emitting member.

In one aspect, forming the alumina may include forming a first alumina structure including irregular protrusions on one side of an aluminum plate by primarily oxidizing the aluminum plate; removing the irregular protrusions; forming a second alumina structure including a plurality of holes by secondarily oxidizing the primarily oxidized aluminum plate; and removing remnant aluminum on the other side of the aluminum plate.

The method may further comprise surface-treating the aluminum plate before the primary oxidizing of the aluminum plate.

The method may further comprise forming a thin film on the alumina structure, the thin film having a different refractive index from the alumina structure, wherein the thin film and the alumina structure comprise a photonic crystal member.

The forming of the thin film may include depositing one of silicon oxide and silicon nitride.

Another exemplary embodiment of the present invention provides a method of forming an organic light emitting diode display, forming an alumina structure having a plurality of holes therein; disposing the alumina structure on the silicon layer; etching the silicon layer using the alumina structure as a mask so as to form a porous silicon structure; removing the alumina structure; forming a thin film on the porous structure, the thin film having a different refractive index from the porous silicon structure; forming a first electrode on the thin film; forming a light emitting member on the first electrode; and forming a second electrode on the light emitting member.

In one aspect, forming the alumina structure may include forming a first alumina structure including irregular protrusions on one side of an aluminum plate by primarily oxidizing the aluminum plate; removing the irregular protrusions; forming a second alumina structure including a plurality of holes by secondarily oxidizing the primarily oxidized aluminum plate; and removing remnant aluminum on the other side of the aluminum plate.

The forming of the thin film may include depositing one of silicon oxide and silicon nitride.

Another exemplary embodiment of the invention provides a display device, including a plurality of signal lines; a plurality of pixels connected to the signal lines and arranged substantially in a matrix; each pixel including a switching transistor, a driving transistor, a storage capacitor, and an organic light emitting diode, wherein the organic light emitting diode further comprises: a substrate; a first electrode formed on the substrate; a second electrode formed on the first electrode; a light emitting member interposed between the first electrode and the second electrode; and a photonic crystal member disposed between the substrate and the first electrode, the photonic crystal member further comprising a porous structure having a plurality of holes and a thin film in contact with the porous structure, the thin film having a different refractive index with respect to the porous structure.

### BRIEF DESCRIPTION OF THE DRAWINGS

The above and other aspects and features of the present invention will become more apparent by describing in detail exemplary embodiments thereof with reference to the attached drawings, in which:

FIG. 1 is a cross-sectional view of a passive OLED according to an exemplary embodiment of the present invention;

FIG. 2 through FIG. 11 are cross-sectional views of the OLED shown in FIG. 1 illustrating intermediate steps of a manufacturing method thereof according to an exemplary embodiment of the present invention;

FIG. 12 is a cross-sectional view of an OLED according to another exemplary embodiment of the present invention;

FIG. 13 is a cross-sectional view of an OLED according to another exemplary embodiment of the present invention;

FIG. 14 through FIG. 19 are cross-sectional views of the OLED shown in FIG. 13 illustrating intermediate steps of a manufacturing method thereof according to an exemplary embodiment of the present invention;

FIG. 20 is an equivalent circuit diagram of an OLED according to an exemplary embodiment of the present invention;

FIG. 21 is a layout view of an OLED according to an exemplary embodiment of the present invention; and

FIG. 22 is a cross-sectional view of the OLED shown in FIG. 21 taken along the line XXII-XXII.

### DETAILED DESCRIPTION OF THE INVENTION

The invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another elements as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments of the present invention are described herein with reference to cross section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present invention.

Hereinafter, the present invention will be described more fully hereinafter with reference to the accompanying drawings, in which exemplary embodiments of the invention are shown.

### Exemplary Embodiment 1

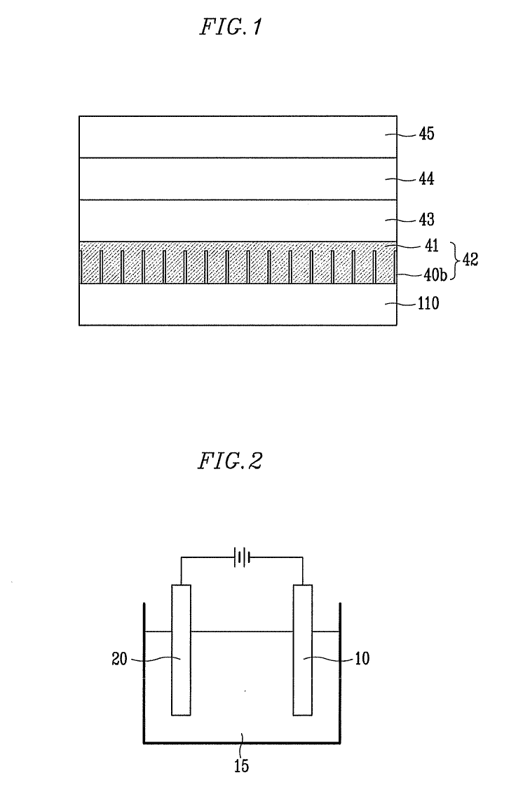

First, an OLED according to an exemplary embodiment of the present invention will be described in detail with reference to FIG. 1.

FIG. 1 is a cross-sectional view of a passive OLED according to an exemplary embodiment of the present invention.

A photonic crystal member 42 is formed on an insulating substrate 110, such as transparent glass or plastic, for example. The photonic crystal member 42 includes an alumina structure 40b and an upper thin film 41. The alumina structure 40b may be formed by oxidizing aluminum (Al) and have a plurality of regular disposed holes. The plurality of holes have diameters ranging from tens to hundreds of nanometers and may be shaped in polygons such as hexagons, for example.

The upper thin film 41 may be made of a material having a different refractive index from the alumina structure 40b. Since the refractive index of the alumina structure 40b is about 1.76 to about 1.78, the upper thin film 41 may be made of a material having a less or greater refractive index than alumina such as, for example, silicon oxide (“SiO₂”) or silicon nitride (“SiNₓ”).

A plurality of lower electrodes 43 are formed on the upper thin film 41. The lower electrodes 43 are formed at predetermined intervals and extend along one direction of the insulating substrate 110. The lower electrodes 43 may be made of a transparent conductive material such as, for example, indium tin oxide (“ITO”) or indium zinc oxide (“IZO”).

An organic light emitting member 44 is formed on the lower electrodes 43. The organic light emitting member 44 may have a multi-layered structure including an emitting layer (not shown) and auxiliary layers (not shown) for improving the light emitting efficiency of the emitting layer.

The emitting layer may be made of an organic material uniquely emitting one of a plurality of primary color lights such as the three primary colors of red, green and blue, or a mixture of the organic material and an inorganic material, or it may be made of tris (8-hydroxyquinoline) aluminum (“Alq3”), anthracene, or a distryl compound. An OLED displays a desired image by the spatial sum of the primary colors of light emitted in the emitting layer.

The auxiliary layers include an electron transport layer (not shown) and a hole transport layer (not shown) for improving the balance of electrons and holes and an electron injection layer (not shown) and a hole injection layer (not shown) for improving the injection of electrons and holes, or they may include one or more layers selected from the above mentioned layers. The hole transport layer and the hole injection layer may be made of a material having a highest occupied molecular orbital (“HOMO”) level that lies between a work function of the lower electrode 43 and HOMO level of the emitting layer, and the electron transport layer and the electron injection layer may be made of a material having a lowest unoccupied molecular orbital (“LUMO”) level that lies between a work function of an upper electrode 45 and LUMO level of the emitting layer.

The upper electrode 45 is made of a conductive material that is suited for electron injection and that does not affect the organic material, such as one selected from aluminum (Al), calcium (Ca), and barium (Ba) for example. In the embodiment depicted, the lower electrode 43 becomes an anode while the upper electrode 45 becomes a cathode, or vice versa.

As described above, the photonic crystal member 42 includes alumina structure 40b and an upper thin film 41 having a different refractive index from the alumina structure 40b. Light generated from the emitting layer of the organic light emitting member 44 sequentially passes through the lower electrode 43, the photonic crystal member 42 and the substrate 110 to be emitted to the exterior of the device. The light periodically passes through the alumina structure 40b and the upper thin film 41 (having different refractive indexes) while it passes through the photonic crystal member 42, in which capture, reflection, path modification of light, and so forth can be regulated. Accordingly, the amount of light emitted toward the front of the device may be increased by controlling the light that is reflected from the substrate 110 or by forming an optical waveguide that is not directed toward the front, thereby increasing the light emitting efficiency. If the light emitting efficiency is increased, a driving voltage of the OLED may be reduced as well as increasing the lifespan thereof.

An exemplary manufacturing method of the OLED shown in FIG. 1 according to an exemplary embodiment of the present invention will now be described in detail with reference to FIG. 2 to FIG. 11, along with FIG. 1.

FIG. 2 through FIG. 11 are cross-sectional views of the OLED shown in FIG. 1 illustrating intermediate steps of a manufacturing method thereof according to an exemplary embodiment of the present invention.

Initially, an exemplary method of forming the alumina structure 40b will first be described with reference to FIG. 2 to FIG. 7.

First, a surface treatment is performed for about 1 minute using an electro-polishing method by applying a voltage on the order of tens of volts to an aluminum substrate 10 having a thickness of about 100 to about 300 μm dipped in an electrolyte, e.g., a mixture of perchloric acid and ethanol at a ratio of about 1:4.

Next, as shown in FIG. 2, the aluminum substrate 10 and an opposite substrate 20 made of platinum or carbon, for example, are partially exposed are immersed in an electrolyte 15 that includes oxalic acid or sulfuric acid whose temperature is less than about 10° C. Then, a primary oxidation of the aluminum substrate 10 is performed at a voltage of about 20 to 80V for a duration of about 4 to 8 hours.

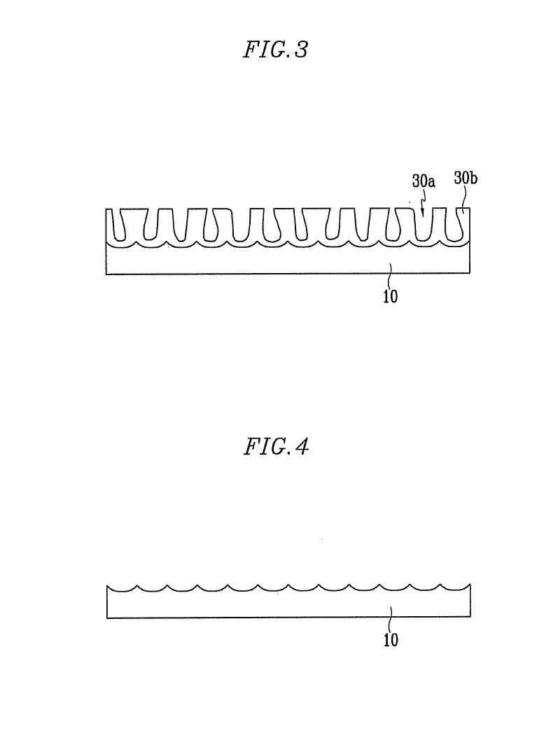

As a result of the primary oxidation, as shown in FIG. 3, a portion of the aluminum substrate 10 exposed to the electrolyte 15 is oxidized to become alumina 30b having holes 30a of irregular size, while the other portion not exposed to the electrolyte 15 remains unaffected.

Then, the aluminum substrate 10 is immersed in a mixed solution of 0.4M of phosphoric acid and 0.2M of chromic acid at a temperature of about 60° C. for about 1 to 3 hours, thereby etching the alumina 30b. Accordingly, as shown in FIG. 4, the alumina 30b formed after the primary oxidation is removed so that only an aluminum substrate 10 is left.

Next, a secondary oxidation is performed on the aluminum substrate 10 following the removal of alumina 30b under substantially the same conditions as the primary oxidation for about 5 to 10 minutes. As a result of the secondary oxidation, as shown in FIG. 5, the aluminum substrate 10 is oxidized to form alumina structure 40b having a plurality of holes 40a.

Then, the aluminum substrate 10 is immersed in a 5 to 10 wt % solution of phosphoric acid at a temperature of about 30 to 40° C. for about 30 to 50 minutes, thereby causing the holes 40a of the alumina 40b to be relatively uniform and large.

Then, as shown in FIG. 6, the aluminum substrate 10 is etched in a mercury chloride solution to form cylindrical holes 40a by removing remaining solid portions of the aluminum substrate 10, except for the porous alumina structure 40b; that is, removing the portion under the line A-A in FIG. 6. Since the mercury chloride solution dissolves only aluminum and not alumina, the aluminum can be selectively etched out.

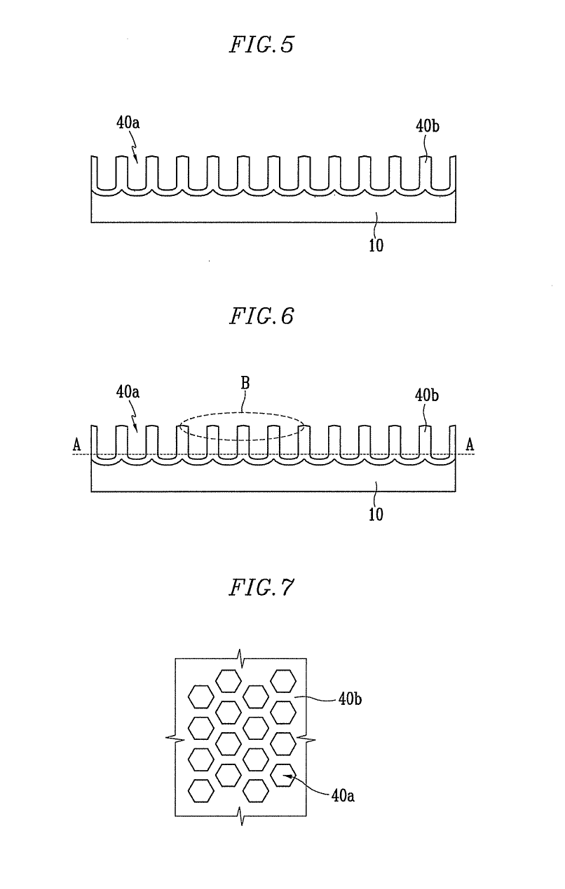

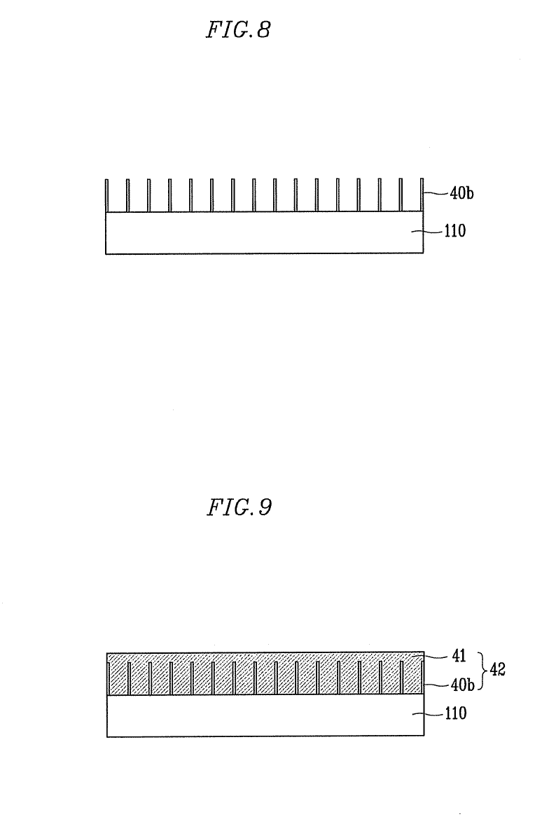

In FIG. 7, which is a magnified top plan view of the portion ‘B’ in FIG. 6, a plurality of holes 40a having uniform shape (such as hexagon) and uniform size are closely disposed with respect to one another.

Next, as shown in FIG. 8, the alumina structure 40b is attached onto an insulating substrate 110. This may be performed in methanol or ethanol, for example.

Then, as shown in FIG. 9, an upper thin film 41, such as one made of SiO₂ or SiNₓ, for example, is deposited on the alumina structure 40b using a chemical vapor deposition (“CVD”) process. The alumina structure 40b and the upper thin film 41 thus form a photonic crystal member 42.

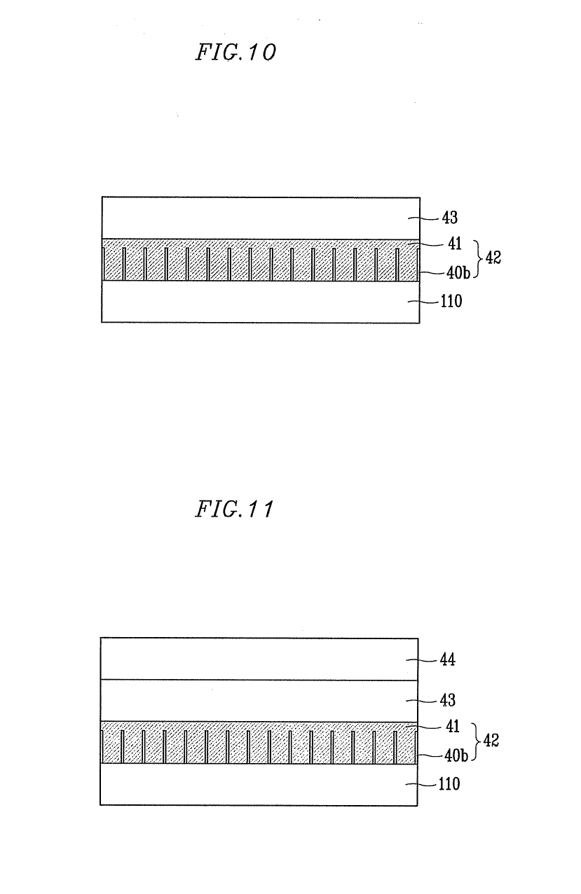

Then, as shown in FIG. 10, a transparent conductor, such as ITO for example, is deposited on the upper thin film 41 such as by sputtering to form lower electrodes 43.

Then, as shown in FIG. 11, an organic light emitting member 44 is deposited on the lower electrode 43. The organic light emitting member 44 may be formed by vacuum evaporation using a shadow mask (not shown) or through a solution process such as Inkjet printing, for example.

Finally, as shown in FIG. 1, upper electrodes 45 are deposited on the organic light emitting member 44.

As thus described above, according to an exemplary embodiment of the present invention, a porous alumina structure formed through a secondary oxidation process is used in the formation a photonic crystal member. As a result of the oxidation conditions, ultra-fine holes on the order of tens to hundreds of nanometers in unit size may be easily formed in the alumina structure through a secondary oxidation process. Moreover, because an ultra-fine photolithography process using laser or electron beams is not required to form the alumina structure, manufacturing costs and time in forming the photonic crystal member 42 can be remarkably reduced.

### Exemplary Embodiment 2

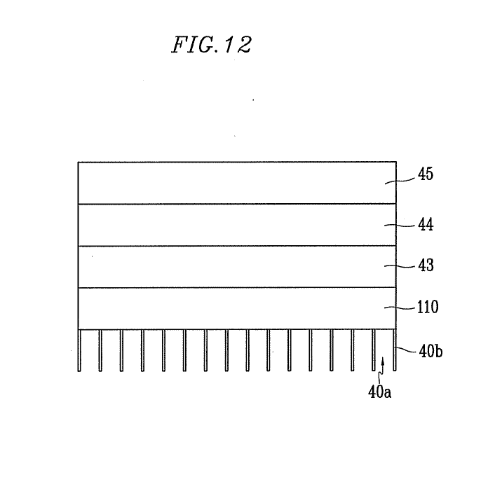

An OLED according to another exemplary embodiment of the present invention will now be described in detail with reference to FIG. 12. For purposes of simplicity, duplicative description with respect to the above-described exemplary embodiment will be omitted.

FIG. 12 is a cross-sectional view of an OLED according to another exemplary embodiment of the present invention.

In the present exemplary embodiment, in contrast to the above-described exemplary embodiment, the photonic crystal member comprises only the alumina structure 40b. In addition, the alumina structure 40b is formed on the outside of the insulating substrate 110.

As shown in FIG. 12, alumina structure 40b is formed on one side of the substrate 110. The alumina structure 40b may be made by oxidizing Al and includes a plurality of regularly disposed holes 40a. The plurality of holes 40a have diameters ranging from tens to hundreds of nanometers, and may be polygon-shaped (such as hexagon, for example).

A plurality of lower electrodes 43 are formed on the other side of the substrate 110. The lower electrodes 43 are formed at predetermined intervals and extend along one direction of the insulating substrate 110. An organic light emitting member 44 is formed on the lower electrodes 43, and upper electrodes 45 are formed on the organic light emitting member 44.

According to the present exemplary embodiment, the photonic crystal member controls the light direction so that light having passed through the substrate 110 can be emitted toward the front of the device. Also, total reflection of light having passed through the substrate 110 at the interface between the substrate 110 and the air is reduced so that the amount of light emitted to the outside can be increased.

### Exemplary Embodiment 3

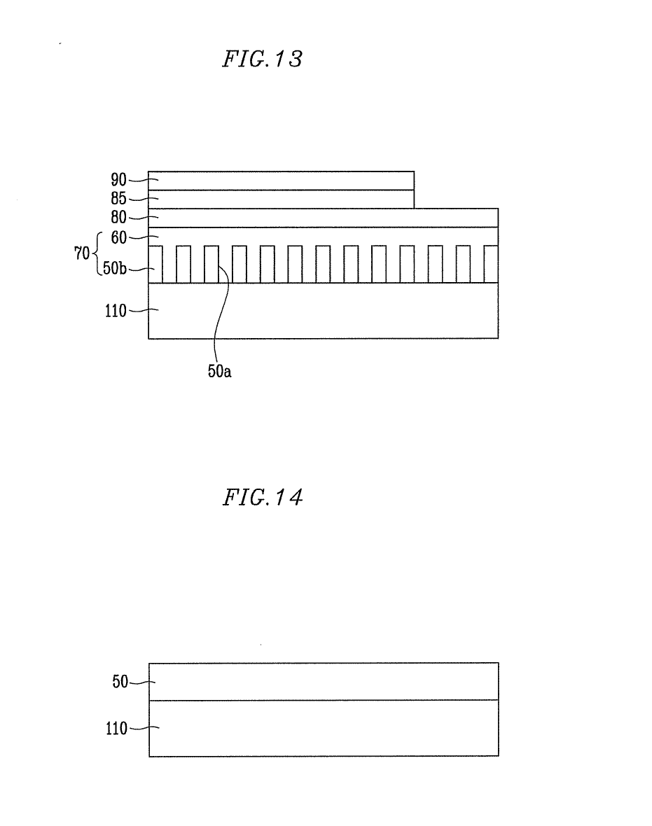

An OLED according to another exemplary embodiment of the present invention will now be described with reference to FIG. 13. Again, duplicative description with respect to the above-described exemplary embodiments will be omitted.

FIG. 13 is a cross-sectional view of an OLED according to another exemplary embodiment of the present invention.

A photonic crystal member 70 is formed on an insulating substrate 110. The photonic crystal member 70 includes a silicon structure 50b and an upper thin film 60.

The silicon structure 50b is made of silicon (Si) and has a plurality of regularly disposed holes 50a. The plurality of holes 50a have diameters on the order of tens to hundreds of nanometers and may be shaped in polygons, such as hexagons for example.

The upper thin film 60 may be made of a material having a different refractive index from that of the silicon forming the silicon structure 50b. Since the refractive index of silicon is about 3.3 to 3.8, the upper thin film 60 may be made of a material having a less or greater refractive index than that, for example, SiO₂ or SiNₓ.

A plurality of lower electrodes 80 are formed on the upper thin film 60. The lower electrodes 80 are formed at predetermined intervals and extend along one direction of the insulating substrate 110. The lower electrodes 80 may be made of a transparent conductive material such as ITO or IZO for example.

An organic light emitting member 85 is formed on the lower electrodes 80. The organic light emitting member 85 may have a multi-layered structure including an emitting layer (not shown) and auxiliary layers (not shown).

Upper electrodes 90 are formed on the organic light emitting member 85. The upper electrodes 90 may be made of a material selected from Al, Ca, and Ba for example.

As described above, the photonic crystal member 70 includes a silicon structure 50b and an upper thin film 60 having a different refractive index from that of the silicon structure 50b. Light emitted from the emitting layer sequentially passes through the lower electrode 80, the photonic crystal member 70 and the substrate 110 to be emitted to the exterior of the device. The light periodically passes through the silicon structure 50b and the upper thin film 60 having different refractive indexes while it passes through the photonic crystal member 70, in which capture, reflection, path modification of light, and so forth can be regulated. Accordingly, the amount of light emitted toward the front of the device may be increased by controlling the light that is reflected from the substrate 110 or by forming an optical waveguide that is not directed toward the front, thereby increasing the light emitting efficiency. If the light emitting efficiency is increased, a driving voltage of the OLED can be reduced as well as increasing the lifespan thereof.

An exemplary manufacturing method of the OLED shown in FIG. 13 according to an exemplary embodiment of the present invention will now be described in detail with reference to FIG. 14 to FIG. 19, along with FIG. 12 and FIG. 2 to FIG. 6.

FIG. 14 through FIG. 19 are cross-sectional views of the OLED shown in FIG. 13 illustrating intermediate steps of a manufacturing method thereof according to an exemplary embodiment of the present invention.

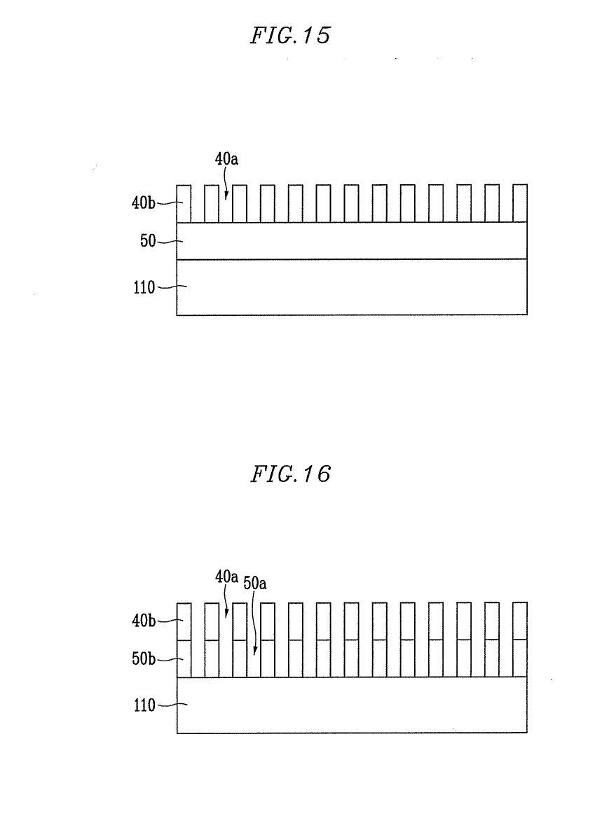

In accordance with the description of the exemplary embodiment 1 illustrated above, an alumina structure 40b having a plurality of holes 40a is prepared according to the method shown in FIG. 2 to FIG. 7. Then, as shown in FIG. 14, a silicon layer 50 is deposited on an insulating substrate 110. As shown in FIG. 15, the alumina structure 40b is attached to the silicon layer 50. This process may be performed in methanol or ethanol.

Then, as shown in FIG. 16, the silicon layer 50 is etched using the alumina structure 40b as a mask so as to form a patterned silicon structure 50b having a plurality of holes 50a. In an exemplary embodiment, the etching is performed at a rate of about 150 nm/min under a pressure of about 50 mTorr, with a chlorine-containing gas supplied at a flow rate of about 70 sccm and an applied voltage of about 450V.

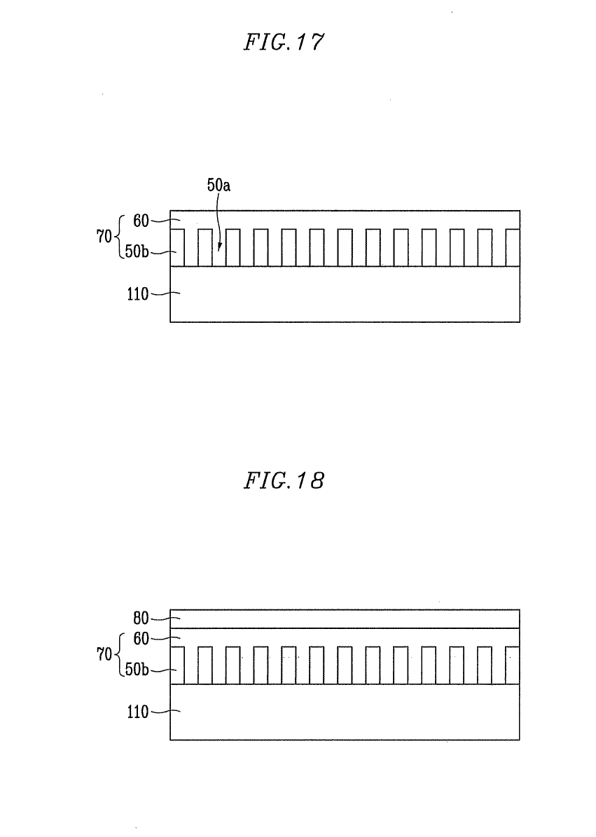

Then, as shown in FIG. 17, an upper thin film 60 preferably made of SiO₂ or SiNₓ is deposited on the silicon pattern 50b by a CVD method. It will be noted that the alumina structure 40b is removed in this embodiment prior to deposition of the upper thin film 60. The silicon pattern 50b and the upper thin film 60 form a photonic crystal member 70.

Then, as shown in FIG. 18, a transparent conductor, such as ITO for example, is deposited on the upper thin film 60 such as by sputtering to form lower electrodes 80.

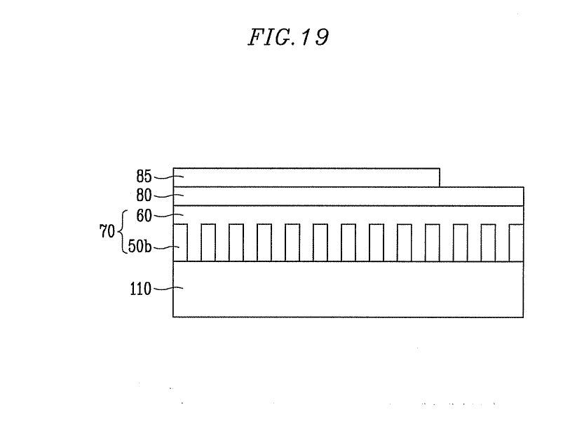

As shown in FIG. 19, an organic light emitting member 85 is then deposited on the lower electrode 80. The organic light emitting member 85 may be formed by vacuum evaporation or by a solution process such as inkjet printing. Finally, as shown in FIG. 13, upper electrodes 90 are deposited on the organic light emitting member 85.

As thus described above, according to an exemplary embodiment of the present invention, a silicon structure, which is used as an element of a photonic crystal member, is formed using a porous alumina mask created by a secondary oxidation process. As a result of the oxidation conditions, ultra-fine holes on the order of tens to hundreds of nanometers in unit size can be easily formed in the alumina structure through a secondary oxidation process. In turn, with the alumina structure used as a mask, a silicon structure having holes of substantially uniform size may be easily formed. Moreover, because an ultra-fine photolithography process using laser or electron beams is not required to form the alumina structure (mask), manufacturing costs and time in forming the photonic crystal member 70 can be remarkably reduced.

### Exemplary Embodiment 4

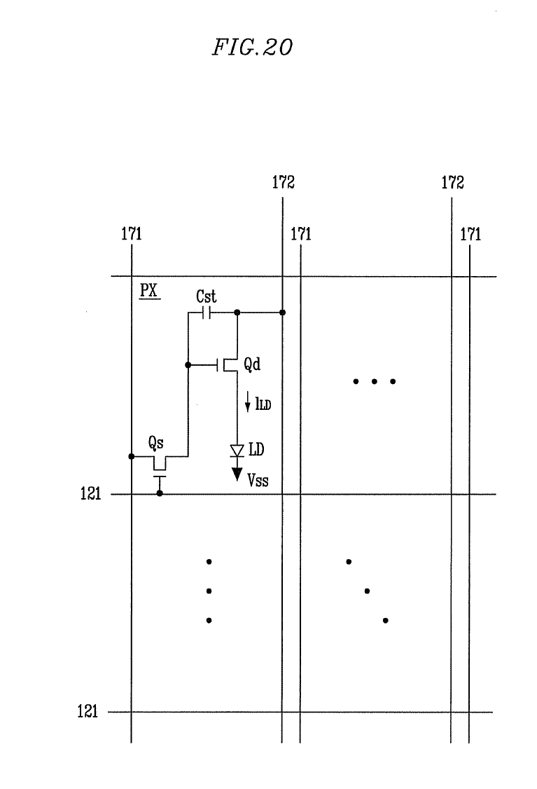

An active OLED according to an exemplary embodiment of the present invention will now be described in detail with reference to FIG. 20 to FIG. 22. Again, duplicative description with respect to the above-described exemplary embodiments will be omitted.

FIG. 20 is an equivalent circuit diagram of an OLED according to an exemplary embodiment of the present invention.

Referring to FIG. 20, an OLED according to the present exemplary embodiment includes a plurality of signal lines 121, 171 and 172 and a plurality of pixels connected to the signal lines 121, 171 and 172, and arranged substantially in a matrix.

More specifically, the signal lines include a plurality of gate lines 121 for transmitting gate signals (or scanning signals), a plurality of data lines 171 for transmitting data signals, and a plurality of driving voltage lines 172 for transmitting a driving voltage. The gate lines 121 extend generally in a row direction and are substantially parallel to each other, and the data lines 171 and the driving voltage lines 172 extend generally in a column direction and are substantially parallel to each other.

Each pixel PX includes a switching transistor Qs, a driving transistor Qd, a storage capacitor Cst, and an organic light emitting diode LD.

Each switching transistor Qs has a control terminal connected to an associated gate line 121, an input terminal connected to an associated data line 171, and an output terminal connected to an associated driving transistor Qd. The switching transistor Qs transmits a data signal applied to the data line 171 to the driving transistor Qd in response to a scanning signal applied to the gate line 121.

A driving transistor Qd also includes a control terminal, an input terminal and an output terminal, where the control terminal is connected to a switching transistor Qs, and the input terminal is connected to a driving voltage line 172, and the output terminal is connected to an organic light emitting diode LD. The driving transistor Qd outputs an output current I_{LD} having an intensity depending on a voltage applied between the control terminal and the output terminal.

The capacitor Cst is connected between a control terminal and an input terminal of a driving transistor Qd. The capacitor Cst stores a data signal applied to the control terminal of the driving transistor Qd and maintains the data even after the switching transistor Qs is turned off.

An organic light emitting diode LD includes an anode connected to an output terminal of a driving transistor Qd and a cathode connected to a common voltage Vss. The organic light emitting diode LD displays an image by emitting light having a varying intensity depending on the output current I_{LD} of the driving transistor Qd.

In an exemplary embodiment, the switching transistor Qs and the driving transistor Qd are n-channel field effect transistors (“FETs”). However, at least one of the switching transistor Qs and the driving transistor Qd may alternatively be a p-channel FET. In addition, the specific connection relationship among the transistors Qs and Qd, the capacitor Cst, and the organic light emitting diode LD may be modified.

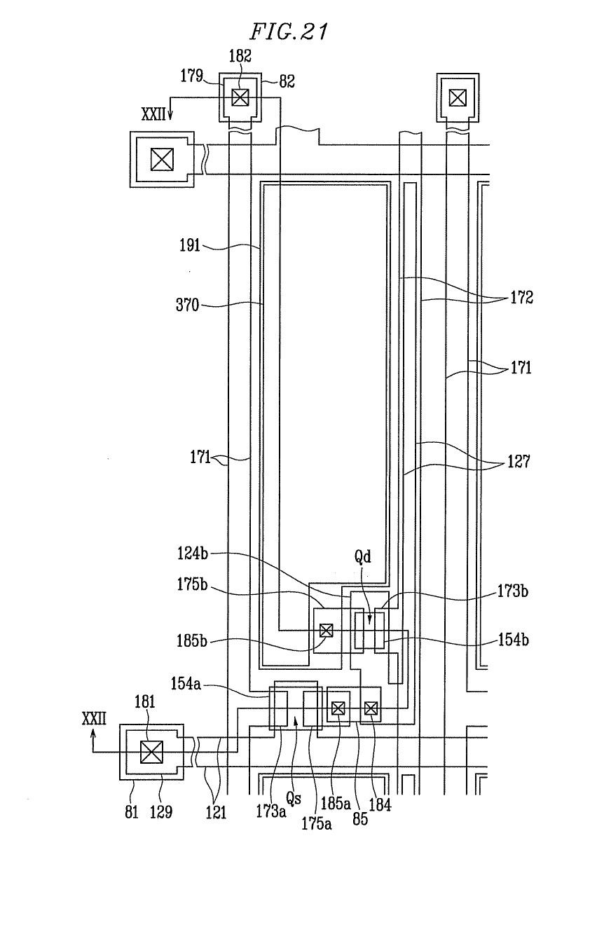

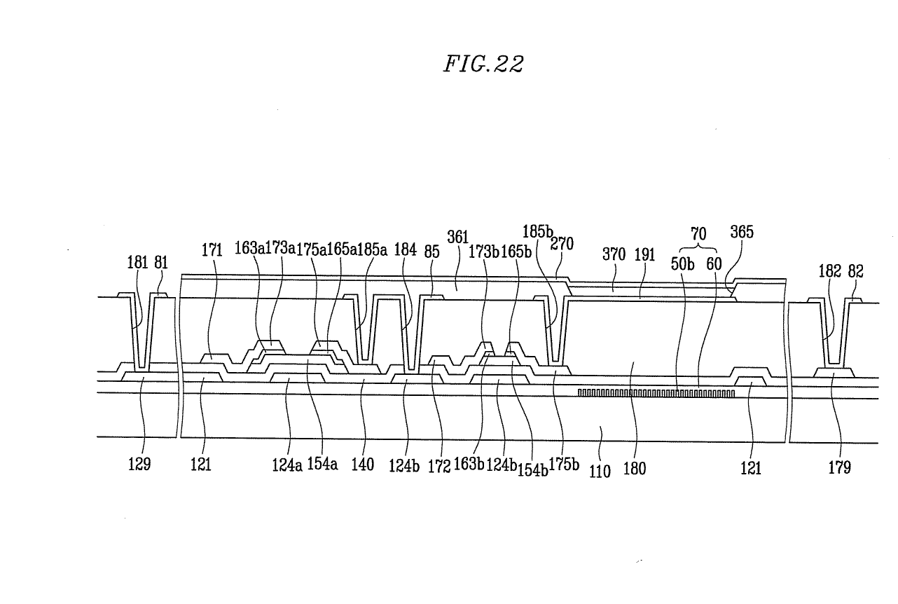

A detailed structure of the OLED shown in FIG. 20 will now be described in detail with reference to FIG. 21 and FIG. 22 along with FIG. 20.

FIG. 21 is a layout view of an OLED according to an exemplary embodiment of the present invention, and FIG. 22 is a cross-sectional view of the OLED shown in FIG. 21 taken along the line XXII-XXII.

A silicon structure 50b, such as one manufactured in the exemplary embodiment 2 is formed on an insulating substrate 110. The silicon structure 50b is formed only on a partial region of the substrate 110, such that this region comprises a light emitting region wherein light is emitted toward the bottom of the substrate 110.

An upper thin film 60 such as one made of SiNₓ or SiO₂, for example, is formed on the silicon structure 50b and the substrate 110. The silicon pattern 50b and the upper thin film 60 form a photonic crystal member 70.

A plurality of gate conductors including a plurality of gate lines 121 having first control electrodes 124a, and a plurality of second control electrodes 124b having storage electrodes 127 are formed on the upper thin film 60.

The gate lines 121 for transmitting gate signals extend substantially in the transverse direction. Each of the gate lines 121 includes an end portion 129 having a large area for connection with another layer or an external driving circuit, and the first control electrode 124a extends upward from the gate line 121. When a gate driving circuit (not shown) generating gate signals is integrated onto the substrate 110, the gate lines 121 may be extended to be directly connected to the gate driving circuit.

The second control electrode 124b, which is separated from the gate line 121, includes a storage electrode 127 extends in a direction substantially parallel to the data lines 171.

The gate conductors 121 and 124b may be made of an aluminum containing metal, such as an Al and Al alloy, a silver (Ag) containing metal such as an Ag and Ag alloy, a copper (Cu) containing metal such as a Cu and Cu alloy, a molybdenum (Mo) containing metal such as a Mo and Mo alloy, chromium (Cr), tantalum (Ta), and titanium (Ti). Alternatively, the gate conductors 121 and 124b may have a multi-layered structure including two conductive layers (not shown) having different physical properties.

The lateral sides of the gate conductors 121 and 124b are inclined relative to a surface of the substrate 110, with an exemplary inclination angle thereof ranging from about 30 degrees to about 80 degrees.

A gate insulating layer 140, such as one made of SiNₓ or SiO₂, for example, is formed on the gate conductors 121 and 124b.

A plurality of semiconductors 154a and 154b, made of hydrogenated amorphous silicon (“a-Si”) or polysilicon, for example are formed on the gate insulating layer 140. The semiconductor 154a overlaps the first control electrode 124a, and the semiconductor 154b is disposed on the second control electrode 124b.

A plurality of pairs of first ohmic contacts 163a and 165a, and a plurality of pairs of second ohmic contacts 163b and 165b are formed on the semiconductors 154a and 154b, respectively. The ohmic contacts 163a, 163b, 165a and 165b are island-shaped and made of, for example, n+ hydrogenated a-Si that is heavily doped with an n-type impurity such as phosphorus (P) or silicide. The first ohmic contacts 163a and 165a are disposed in pairs on the semiconductor 154a, and the second ohmic contacts 163b and 165b are also disposed in pairs on the semiconductor 154b.

A plurality of data conductors, including a plurality of data lines 171, a plurality of driving voltage lines 172, and a plurality of first and second output electrodes 175a and 175b are formed on the ohmic contacts 163a, 163b, 165a and 165b and the gate insulating layer 140.

The data lines 171 for transmitting data signals extend substantially in the longitudinal direction and intersect the gate lines 121. Each data line 171 includes a plurality of first input electrodes 173a branching out toward the first control electrode 124a, and an end portion 179 having a large area for connection with another layer or an external driving circuit. When a data driving circuit (not shown) is integrated on the substrate 110, the data lines 171 may be extended to be directly connected to the data driving circuit.

The driving voltage lines 172 for transmitting a driving voltage extend substantially in the longitudinal direction and intersect the gate lines 121. Each driving voltage line 172 includes a plurality of second input electrodes 173b branching out toward the second control electrode 124b, and includes an overlapping portion with the storage electrode 127.

The first and the second output electrodes 175a and 175b are separated from each other, and are also separated from the data line 171 and the driving voltage line 172. The first input electrode 173a and the first output electrode 175a oppose one other on the semiconductor 154a, while the second input electrode 173b and the second output electrode 175b oppose one other on the semiconductor 154b.

The data conductors 171, 172, 175a and 175b are made of a refractory metal such as, for example, Mo, Cr, Ta, and Ti or an alloy thereof. Also, the data line 171 and the drain electrode 175 may have a multi-layered structure including a refractory metal layer (not shown) and a conductive layer (not shown) having low resistivity.

Like the gate conductors 121 and 124b, the lateral sides of the data conductors 171, 172, 175a and 175b are also inclined relative to a surface of the substrate 110, with the inclination angles thereof in an exemplary range of about 30 degrees to about 80 degrees.

The ohmic contacts 163a, 163b, 165a and 165b are interposed only between the underlying semiconductors 154a and 154b, and the overlying data conductors 171, 172, 175a and 175b thereon and reduce the contact resistance therebetween. The semiconductors 154a and 154b include exposed portions which are not covered with the data conductors 171, 172, 175a and 175b, such as portions located between the input electrodes 173a and 173b and the output electrodes 175a and 175b.

A passivation layer 180 is formed on the data conductors 171, 172, 175a and 175b and the exposed portions of the semiconductors 154a and 154b. The passivation layer 180 is preferably made of an inorganic insulator or an organic insulator and the surface thereof may be flat.

The passivation layer 180 has a plurality of contact holes 182, 185a and 185b respectively exposing the end portions 179 of the data lines 171 and the first and the second output electrodes 175a and 175b, and the passivation layer 180. The gate insulating layer 140 has a plurality of contact holes 181 and 184 respectively exposing the end portions 129 of the gate lines 121 and the second input electrodes 124b.

A plurality of pixel electrodes 191, a plurality of connecting members 85, and a plurality of contact assistants 81 and 82 are formed on the passivation layer 180. These elements may be made of a transparent conductor such as ITO or IZO, for example, or a reflective metal such as Al, Ag, Cr, or an alloy thereof.

The pixel electrode 191 is physically and electrically connected to the second output electrode 175b through the contact hole 185b. The connecting member 85 is connected to the second control electrode 124b and the first output electrode 175a through the contact holes 184 and 185a.

The contact assistants 81 and 82 are connected to the end portion 129 of the gate line 121 and the end portion 179 of the data line 171 through the contact holes 181 and 182, respectively. The contact assistants 81 and 82 supplement the adhesive property of the end portions 129 and 179 of the gate lines 121 and the data lines 171 to exterior devices, protecting the same.

A partition 361 is formed on the passivation layer 180. The partition 361 encloses the pixel electrode 191 to define a bank-like opening 365 on the pixel electrode 191. In an exemplary embodiment, the partition 361 is made of an organic or inorganic insulating material. In addition, the partition 361 may be made of a photosensitive material containing black pigment. In the embodiment depicted, the partition 361 functions as a light blocking member, and the formation thereof is simplified.

Further, organic light emitting members 370 are formed in the openings 365. Each of the organic light emitting members 370 is made of an organic material uniquely emitting one of a plurality of primary color lights such as the three primary colors of red, green, and blue. An OLED displays a desired image by the spatial sum of the primary colors of light emitted by the organic light emitting members 370. The organic light emitting member 370 may have a multi-layered structure including an emitting layer (not shown) and auxiliary layers (not shown) for improving the light emitting efficiency of the emitting layer.

A common electrode 270 is formed on the organic light emitting member 370. An encapsulation layer (not shown) may be formed on the common electrode 270. The encapsulation layer encapsulates the organic light emitting members 370 and the common electrode 270 so as to prevent moisture and/or oxygen from infiltrating therein.

In such an OLED, a first control electrode 124a connected to a gate line 121, a first input electrode 173a connected to a data line 171, and a first output electrode 175a, along with a semiconductor 154a, form a switching thin film transistor (switching TFT) Qs, the channel of which is formed in the semiconductor 154a disposed between the first input electrode 173a and the first output electrode 175a. A second control electrode 124b connected to a first output electrode 175a, a second input electrode 173b connected to a driving voltage line 172, and a second output electrode 175b connected to a pixel electrode 191, along with a semiconductor 154b, form a driving thin film transistor (driving TFT) Qd, the channel of which is formed in the semiconductor 154b disposed between the second input electrode 173b and the second output electrode 175b. In order to increase the driving current, the channel width of the driving TFT Qd may be increased or the channel length thereof may be decreased.

A pixel electrode 191, an organic light emitting member 370 and the common electrode 270 form an OLED LD, in which the pixel electrode 191 becomes an anode while the common electrode 270 becomes a cathode, or vice versa. Also, a storage electrode 127 and a driving voltage line 172 overlapping the storage electrode 127 form a storage capacitor Cst.

The exemplary OLED described herein is a bottom emission type OLED that emits light toward the bottom of the substrate 110, in which light generated from an organic light emitting member 370 passes through a pixel electrode 191, the passivation layer 180, the gate insulating layer 140, a photonic crystal member 70 and the substrate 110 so as to be emitted to the outside. The light periodically passes through the silicon structure 50b and the upper thin film 60 having different refractive indexes while it passes through the photonic crystal member 70, such that capture, reflection, path modification of light, and so forth can be regulated. Accordingly, the amount of light emitted toward the front of the device may be increased by controlling the light that is reflected from the substrate 110 or by forming an optical waveguide that is not directed toward the front, thereby increasing the light emitting efficiency. If the light emitting efficiency is increased, a driving voltage of the OLED can be reduced as well as increasing the lifespan thereof.

In the above description, although the photonic crystal member 70 is described to include a silicon structure 50b, it is also contemplated that the photonic crystal member 70 may include the alumina structure 40b as in exemplary embodiments 1 and 3 described above.

Moreover, even though the photonic crystal member 70 is depicted as being disposed directly on the substrate 110, the embodiments herein are not limited to such an arrangement, as the photonic crystal member 70 may alternatively be disposed in any layer between the substrate 110 and the pixel electrode 191. Also, even though a bottom emission type OLED of is described above, the above-described exemplary embodiment may be also applied to a top emission type OLED in which light is emitted toward the common electrode 270 in the same manner. In this case, the photonic crystal member may be formed on the side of the common electrode 270 toward which light is emitted.

Further, in event that the semiconductors 154a and 154b are polysilicon, they may include intrinsic regions (not shown) opposing the control electrodes 124a and 124b and extrinsic regions (not shown) disposed on both sides of the intrinsic regions. The extrinsic regions are electrically connected to the input electrodes 173a and 173b and the output electrodes 175a and 175b, and the ohmic contacts 163a, 163b, 165a and 165b may be omitted.

Also, the control electrodes 124a and 124b may be disposed on the semiconductors 154a and 154b, and the gate insulating layer 140 may be disposed between the semiconductors 154a and 154b and the control electrodes 124a and 124b. In this instance, the data conductors 171, 172, 173b and 175b are disposed on the gate insulating layer 140, and may be electrically connected to the semiconductors 154a and 154b through contact holes (not shown) penetrating the gate insulating layer 140. Alternatively, the data conductors 171, 172, 173b and 175b may be disposed under the semiconductors 154a and 154b and electrically contact with the semiconductors 154a and 154b thereon.

By configuring photonic crystal members in accordance with one or more of the above described embodiments, an amount of light emitted toward the front of the device may be increased by controlling the light that is reflected from a substrate or by forming an optical waveguide that is not directed toward the front, thereby increasing the light emitting efficiency, and accordingly, a driving voltage of an OLED can be reduced as well as increasing the lifespan thereof. Also, since the photonic crystal member can be formed to have ultra-fine holes of tens to hundreds of nanometers in unit size through oxidation processes, the manufacturing cost and time can be remarkably reduced.

Although preferred embodiments of the present invention have been described in detail hereinabove, it should be clearly understood that many variations and/or modifications of the basic inventive concepts herein taught, which may appear to those skilled in the present art, will still fall within the spirit and scope of the present invention, as defined in the appended claims.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. An organic light emitting device comprising:
a substrate;
a first electrode formed on the substrate;
a second electrode formed on the first electrode;
a light emitting member interposed between the first electrode and the second electrode; and
a photonic crystal member formed proximate the substrate.

2. The organic light emitting device of claim 1, wherein the photonic crystal member is disposed between the substrate and the first electrode and further comprises a porous structure having a plurality of holes and a thin film in contact with the porous structure, the thin film having a different refractive index with respect to the porous structure.

3. The organic light emitting device of claim 2, wherein the porous structure comprises alumina.

4. The organic light emitting device of claim 2, wherein the porous structure comprises silicon.

5. The organic light emitting device of claim 3, wherein the thin film comprises one of silicon oxide and silicon nitride.

6. The organic light emitting device of claim 5, wherein a diameter of the holes of the porous structure is from about tens of nanometers to about hundreds of nanometers.

7. The organic light emitting device of claim 4, wherein the thin film comprises one of silicon oxide and silicon nitride.

8. The organic light emitting device of claim 7, wherein a diameter of the holes of the porous structure is from about tens of nanometers to about hundreds of nanometers.

9. The organic light emitting device of claim 1, wherein the photonic crystal member is disposed under the substrate and includes a plurality of holes therein.

10. The organic light emitting device of claim 9, wherein the photonic crystal member comprises alumina.

11. The organic light emitting device of claim 9, wherein a diameter of the holes is from about tens of nanometers to about hundreds of nanometers.

12. A method of forming an organic light emitting device, the method comprising:
forming an alumina structure having a plurality of holes therein;
disposing the alumina structure on a substrate;
forming a first electrode on the substrate;
forming a light emitting member on the first electrode; and
forming a second electrode on the light emitting member.

13. The method of claim 12, wherein forming the alumina structure comprises:
forming a first alumina structure including irregular protrusions on one side of an aluminum plate by primarily oxidizing the aluminum plate;
removing the irregular protrusions;
forming a second alumina structure including a plurality of holes by secondarily oxidizing the primarily oxidized aluminum plate; and
removing remnant aluminum on the other side of the aluminum plate.

14. The method of claim 13, further comprising surface-treating the aluminum plate before the primary oxidizing of the aluminum plate.

15. The method of claim 13, further comprising forming a thin film on the alumina structure, the thin film having a different refractive index from the alumina structure, wherein the thin film and the alumina structure comprise a photonic crystal member.

16. The method of claim 15, wherein forming the thin film further comprises depositing one of silicon oxide and silicon nitride.

17. A method of forming an organic light emitting diode display, the method comprising:
forming a silicon layer on a substrate;
forming an alumina structure having a plurality of holes therein;
disposing the alumina structure on the silicon layer;
etching the silicon layer using the alumina structure as a mask so as to form a porous silicon structure;
removing the alumina structure;
forming a thin film on the porous silicon structure, the thin film having a different refractive index from the porous silicon structure;
forming a first electrode on the thin film;
forming a light emitting member on the first electrode; and
forming a second electrode on the light emitting member.

18. The method of claim 17, wherein forming the alumina structure comprises:
forming a first alumina structure including irregular protrusions on one side of an aluminum plate by primarily oxidizing the aluminum plate;
removing the irregular protrusions;
forming a second alumina structure including a plurality of holes by secondarily oxidizing the primarily oxidized aluminum plate; and
removing remnant aluminum on the other side of the aluminum plate.

19. The method of claim 18, wherein forming the thin film further comprises depositing one of silicon oxide and silicon nitride.

20. A display device, comprising:
a substrate;
a plurality of signal lines formed on the substrate;
a plurality of pixels connected to the signal lines and arranged substantially in a matrix;
each pixel including a switching transistor, a driving transistor, a storage capacitor, and an organic light emitting diode, wherein the organic light emitting diode further comprises:
a first electrode;
a second electrode formed on the first electrode;
a light emitting member interposed between the first electrode and the second electrode; and
a photonic crystal member disposed between the substrate and the first electrode, the photonic crystal member further comprising a porous structure having a plurality of holes and a thin film in contact with the porous structure, the thin film having a different refractive index with respect to the porous structure.

21. The display device of claim 20, wherein the porous structure comprises alumina.

22. The display device of claim 21, wherein the thin film comprises one of silicon oxide and silicon nitride.

23. The display device of claim 20, wherein the porous structure comprises silicon.

24. The display device of claim 23, wherein the thin film comprises one of silicon oxide and silicon nitride.
